(19) United States
(12) Patent Application Publication
(10) Pub. No.: US 2025/0244412 A1
(43) Pub. Date: Jul. 31, 2025

(54) MAGNETIC FIELD SENSOR

(71) Applicant: NewSouth Innovations Pty Limited, Sydney (AU)

(72) Inventors: Dane MCCAMEY, Sydney (AU); Rugang GENG, Sydney (AU); William PAPPAS, Sydney (AU); Adrian MENA, Sydney (AU)

(73) Assignee: NewSouth Innovations Pty Limited, Sydney (AU)

(21) Appl. No.: 18/877,650

(22) PCT Filed: Jun. 23, 2023
(86) PCT No.: PCT/AU2023/050577

§ 371 Date: Dec. 20, 2024

(30) Foreign Application Priority Data
Jun. 23, 2022 (AU) 2022901738

(51) Int. Cl. G01R 33/00; G01R 33/10; G01R 33/24; G01R 33/32

(52) U.S. Cl. CPC G01R 33/0005; G01R 33/10; G01R 33/24; G01R 33/323

(57) ABSTRACT

A magnetic field sensor 1 includes an electrically inert and optically clear substrate 4 that has opposed upper and lower surfaces. A microwave or RF generator element 13 is disposed on the upper side of the substrate where the generator element 13 is configured to be connected to an electrode for connection to a microwave or RF generator. The sensor 1 includes a heterostructure organic light emitting diode (OLED) 2 disposed adjacent the microwave or RF generator element 6, the OLED being configured to be connected to a first electrode and a second electrode.

### FIELD OF THE INVENTION

The present invention relates to magnetic field sensing and, in particular, to an optically readable low strength magnetic field sensor.

A preferred embodiment of the invention will be described with reference to 2-dimensional spatially resolved low magnetic field strength detection, however, it will be appreciated the invention is not limited to this particular application and may spatially resolve low magnetic field strength in one or three dimensions.

### BACKGROUND OF THE INVENTION

Quantum sensing and imaging of magnetic fields have attracted broad interest due to their potential for high sensitivity and spatial resolution. Common quantum sensing techniques require either optical excitation (e.g., nitrogen-vacancy centres in diamond, atomic vapor magnetometers), or cryogenic temperature (e.g. SQUIDs, superconducting qubits), which poses challenges for chip-scale integration and commercial scalability.

Magnetic field sensing and mapping are important for many scientific and technological applications across both physical and biological systems. Compared to classical methods, quantum sensing techniques have decisive advantages, including high sensitivity in field detection and high spatial resolution in field mapping. Among the many quantum techniques, nitrogen-vacancy (NV) centres in diamonds have emerged as an outstanding sensor platform, and have demonstrated room-temperature pico-tesla level sensitivities, nanoscale spatial resolution and good integration and miniaturization.

Meanwhile, organic semiconductors (OSCs) are proven to be extremely sensitive to magnetic fields, and OSC-based solid-state devices have been proposed as a new type of quantum sensor. Unlike NV-based techniques, OSC-based magnetic sensors do not require optical pumping; moreover, they can provide both electrical and optical readout via optically and electrically detected magnetic resonance (ODMR and EDMR, respectively). EDMR allows for chip-scale integration of a single point-like sensor. Additionally, ODMR allows simultaneous acquisition of optical signals in the field of view, enabling spatially resolved sensing and imaging. OSCs are also inherently compatible with mass-produced consumer electronics, providing a potential pathway for ubiquitous deployment.

### OBJECT OF THE INVENTION

The object of the invention is a desire to provide a spatially resolved low magnetic field strength detection apparatus that overcomes one or more of the disadvantages of the prior art, or to provide a useful alternative.

### SUMMARY OF THE INVENTION

In accordance with a first aspect of the present invention there is disclosed a magnetic field sensor comprising: an electrically inert and optically clear substrate having upper and lower surfaces; a microwave or radio frequency (RF) generator element disposed on an upper side of the substrate, the generator element configured to be connected to an electrode for connection to a microwave or RF generator; and a heterostructure organic light-emitting diode (OLED) disposed adjacent the microwave or RF generator element, the OLED being configured to be connected to a first electrode and a second electrode.

In accordance with a second aspect of the invention there is provided a magnetic field sensor comprising: one or more spaced apart electrically inert and optically clear substrates having upper and lower surfaces; a plurality of spaced apart microwave or RF generator elements disposed on one substrate or one or more microwave or RF generator elements disposed on an upper side of each substrate, the microwave or RF generator elements each configured to be connected to an electrode for connection to a microwave or RF generator; and a heterostructure organic light emitting diode (OLED) disposed adjacent each microwave or RF generator element, each OLED being configured to be connected to a first electrode and a second electrode.

According to another aspect of the invention there is provided a magnetic field sensor comprising: an electrically inert and optically clear substrate having upper and lower surfaces; a microwave or RF generator element disposed on an upper side of the substrate, the microwave or RF generator element configured to be connected to an electrode for connection to a microwave or RF generator; and a plurality of heterostructure organic light emitting diodes (OLEDs) disposed adjacent the microwave or RF generator element, each OLED being configured to be connected to a first electrode and a second electrode.

It can therefore be seen there is advantageously provided a spatially resolved low magnetic field apparatus that is able to be disposed on a single chip which does not require optical-pumping or cryogenic temperatures. Furthermore, an integrated OLED based quantum sensor for magnetic field imaging, which employs spatially resolved magnetic resonance to provide a robust mapping of magnetic fields, overcomes the significant technical challenge of integrating a resonator with an OLED on the same substrate while having suitable electrical isolation of the resonator and OLED (optical readout). In the preferred embodiment described below, an optical imaging system achieved magnetic field mapping with field sensitivity of ˜160 μT Hz^{-1/2} μm⁻². Such validates the potential for a chip-scale OLED-based laser free approach for magnetic field sensing and mapping. An array of sensors can be disposed on a single substrate in one, two or three dimensions, or across multiple substrates.

### BRIEF DESCRIPTION OF THE DRAWINGS

A preferred embodiment of the invention will now be described, by way of example only, with reference to the accompanying drawings in which:

FIG. 1 is a schematic diagram of a magnetic field sensor according to the preferred embodiment of the invention including an integrated device and EDMR characterisation thereof;

FIG. 2 is a schematic diagram of EDMR magnetic field sensing apparatus together with results thereof for the sensor of FIG. 1;

FIG. 3 is a schematic diagram of ODMR magnetic field sensing apparatus together with results thereof for the sensor of FIG. 1;

FIG. 4 shows the magnetic field gradient sensitivity of the sensor of FIG. 1;

FIG. 5 shows the fabrication steps of the microwave resonator of the sensor of FIG. 1;

FIG. 6 shows the shadow mask for the OLED of the sensor of FIG. 1;

FIG. 7 indicates detected background noise of connecting cable and the resonator of the sensor of FIG. 1;

FIG. 8 shows signal and noise data of an EDMR signal of the sensor of FIG. 1;

FIG. 9 shows the measurement of the angle dependent EDMR of the device of FIG. 1;

FIG. 10 shows an apparatus for use with frequency swept EDMR measurements of the device of FIG. 1;

FIG. 11 illustrates simulated and measured magnetic fields of the device of FIG. 1;

FIG. 12 shows standard error for spatially resolved ODMR data with different bin sizes in a local region of the device of FIG. 1;

FIG. 13 shows standard error for spatially resolved ODMR data in the full field of view of the device of FIG. 1;

FIG. 14 shows standard error of ODMR spectra of different bin sizes for the device of FIG. 1; and

FIG. 15 shows results of a calculation of the sensitivity of the spatially resolved ODMR of the device of FIG. 1

### DESCRIPTION OF THE PREFERRED EMBODIMENT

Referring to the drawings of the preferred embodiments generally, like reference numerals have been used to denote like components unless expressly denoted to the contrary.

It is firstly noted the principle of optically and electrically detected magnetic resonance relies on the spin-dependent recombination and dissociation dynamics in an OLED. When positive and negative charge carriers are injected from anode and cathode they initially bind together electrostatically to form polaron pairs in the emissive layer. These polaron pairs can have either singlet or triplet dominant character depending on their spin configuration and a transition occurs between them via spin mixing. Polaron pairs can further recombine to form singlet or triplet excitons or dissociate back to free charge carriers with a rate dependent on their singlet-triplet symmetry. Under magnetic resonance (f=γB₀, where f is the microwave frequency, γ is the gyromagnetic ratio and B₀ is the applied magnetic field), the spin orientations of charge-carriers in polaron pairs are manipulated which causes a change of the population ratio of singlet to triplet pairs. The population change is eventually transferred to the electroluminescence (EL) and the current through the recombination and dissociation process, respectively, leading to a change in both EL and current.

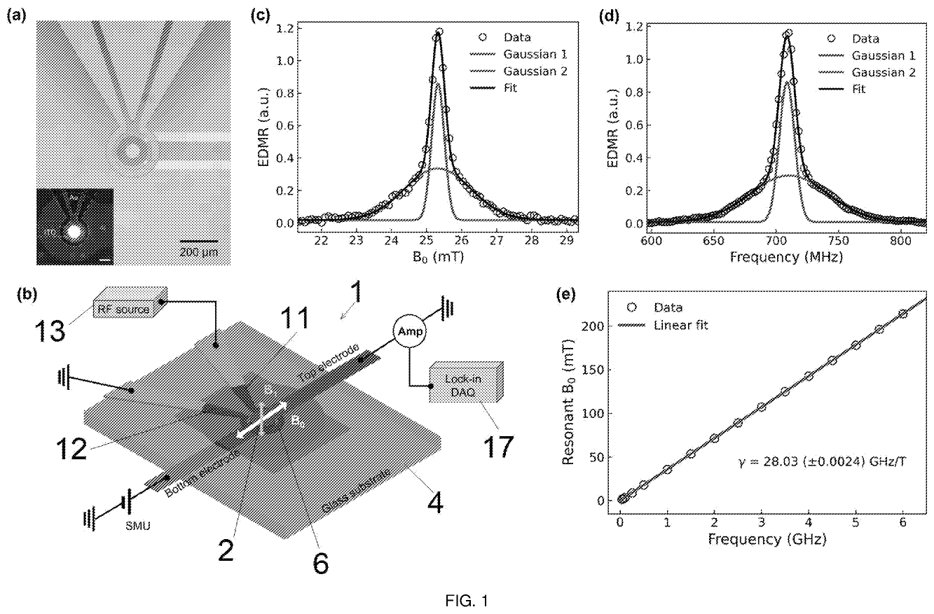

The preferred embodiment of the present invention provides an integrated solid-state device 1 to detect and image a magnetic field whereby an OLED 2 and a microwave resonator 3 are laterally integrated on the same substrate 4 (FIG. 1a). The device 1 architecture allows measurement of magnetic field both electrically (via EDMR) and optically (via ODMR). The device 1 can act not only as a point sensor by measuring its bulk EDMR or ODMR spectroscopy, but also as a virtual array of sensors 10 through the spatially resolved ODMR. The latter advantageously offers a route for fast magnetic mapping without point-to-point scanning by using a camera to generate a virtual array, which may have potential applications in quantum magnetic sensing and imaging. The generated microwave field of the split ring resonator is sufficient for spin resonance even when not driven on resonance.

Referring to FIG. 1, the device 1 structure is shown. FIG. 1(a) is a photograph of a microwave resonator 3 based template where an omega-shaped resonator element 6 that is integrated on a prepatterned ITO/glass substrate 4. However, it will be appreciated that in other preferred embodiments the substrate is a rigid or flexible plastic. Generally, the resonator element 6 can be termed OMEGA-shaped in view of the resemblance to the Greek letter (but is described in the preferred embodiment as a planar ring 7 having an open arc length 8 defining a chord length disposed between respective ends 9 and 10. The ends 9 & 10 of the ring 7 are connected to respective electrodes 11 & 12 of a microwave source 13. It can be seen microwave resonator 3 includes element 6 and electrodes or legs 11,12.

The active area in the centre of ring 7 has a diameter of 80 μm, which is defined through photolithography and insulating layer deposition. The inset shows the photograph of an integrated OLED 2 at current of I=500 nA (corresponding current density of ˜10 mA/cm²). FIG. 1(b) shows a sketch of the integrated device 1 structure and the experimental measurement configuration, employed with the AC magnetic field B₁ created by the microwave resonator 3 and the static magnetic field B₀ generated by an external electromagnet 14 (not shown in FIG. 1b).

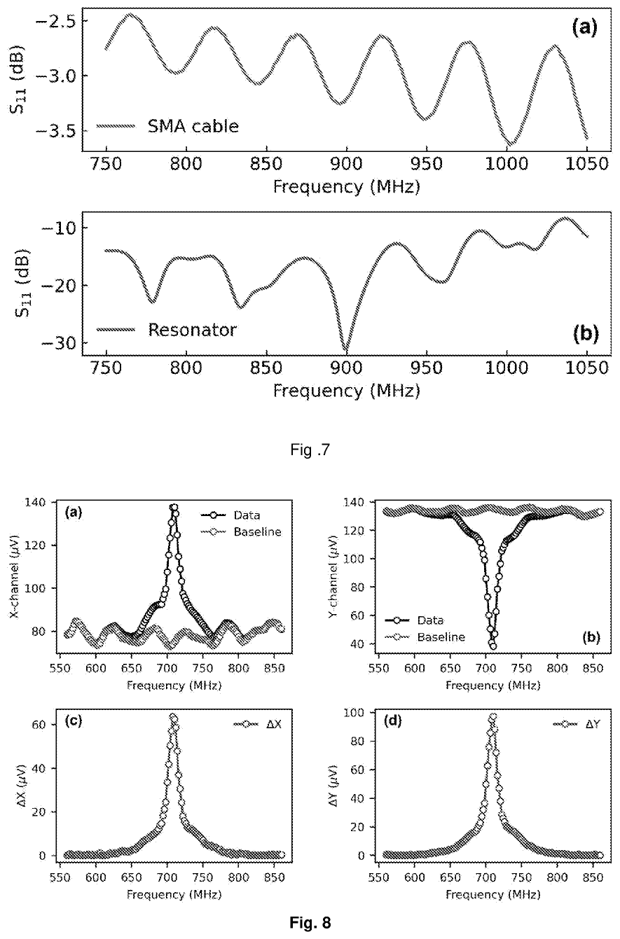

FIG. 1(c) is a conventional EDMR spectrum where the static magnetic field B₀ is swept with a fixed microwave frequency of 710 MHz. The spectrum is well described by the sum (black) of two Gaussian functions (red, blue), corresponding to the two hyperfine-field distributions (σ₁=0.18(2), σ₂=0.94(2)) experienced by the electron and hole spins, respectively. σ₁ and σ₂ represent the standard deviation of the two Gaussian functions. FIG. 1(d) shows a frequency-swept EDMR spectrum where the microwave frequency is swept with a fixed magnetic field B₀≈25.2(5) mT via fixing the current in the electromagnet 14. The spectrum can be well fitted using two Gaussian functions with standard deviation of σ₁=6.15(1) and σ₂=31.23(0), respectively. We note that the background noise caused by the frequency sweep is removed from the plots in FIG. 1(d). More details are discussed below with reference to FIGS. 7 & 8 below. FIG. 1(e) is a plot of the maximum-peak value of the magnetic field B₀ in the EDMR spectrum as a function of applied microwave frequency. A linear fit (red line) of the data yields a gyromagnetic ratio γ=28.03 (±0.0024) GHz/T and a corresponding g-factor g=2.0026 (±0.00017).

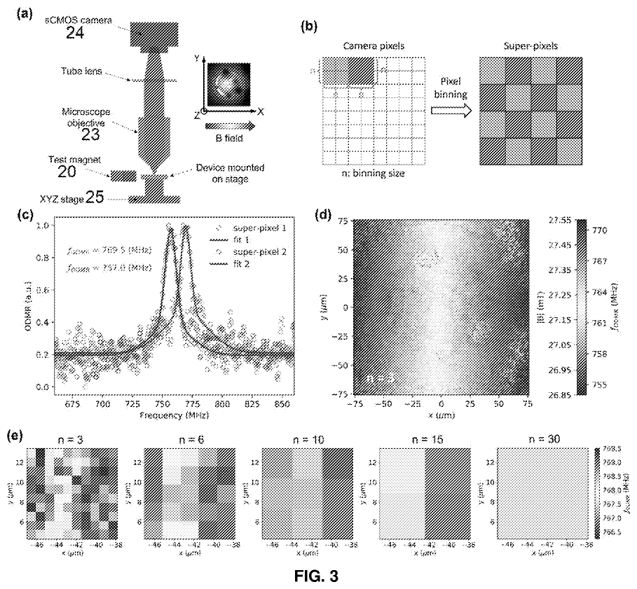

FIGS. 7 & 8 show a “wobbling” feature noise in the raw magnetic resonant spectrum with sweeping the microwave frequency. It is believed this noise originates from the microwave component in the experimental setup as a similar “wobbling” feature is seen in the S₁₁ curve of the SMA cable 16 (see FIG. 7(a)) itself, which is connected to the microwave source 6 directly via connector 16A, which might be due to the mismatch of 50Ω impedance of the RF output, resulting in some end-reflection of the signal in the cable 16. FIG. 7(b) is the microwave resonator 3 connected to the microwave source 13 through the PCB. Such noise is then transmitted and modified through the PCB and the resonator, and eventually coupled to the OLED 2, resulting in those “wobbling” feature noise in the final EDMR spectrum (see FIG. 8). In addition, the amplitude of the noise is not a constant, but varies at different microwave frequency (see FIG. 3). Such baseline noise can be measured separately and then subtracted from the data where FIG. 8 shows the raw signal and background noise in FIG. 8(a) x-channel and FIG. 8(b) y-channel in the lock-in detection where the microwave frequency is swept. The signal in (a) x-channel and (b) y-channel after the noise is subtracted. The final EDMR signal is given by ΔR=\sqrt{(Δx)²+(Δy)²} with negative sign.

The device 1 structure consists of two main components: the omega-shape microwave resonator 3 with element 6 having electrodes 11, 12, and a micron-size heterostructure OLED 2 located at the centre of the resonator 3 (FIG. 1b). The microwave resonator 3 is electrically isolated from the OLED 2 by employing two insulating layers between them (described further below). FIG. 1(a) displays the resonator-integrated template on substrate 4 before the inclusion of OLED 2, and the inset shows the completed device where the OLED 2 was illuminated or turned on at current I=500 nA with bright and uniform electroluminescence. The EDMR characteristics of the device 1 was first tested. FIG. 1(c) shows a typical EDMR spectrum where the microwave frequency is fixed (710 MHZ) and the external magnetic field B₀ is swept. The EDMR signal (the current change) reaches its maximum at B₀˜25.3 (3) mT, in a good agreement with the magnetic resonant condition. The EDMR spectrum can be fit using two Gaussian functions as expected in the polaron pair process in OSCs, corresponding to the two charge carrier species. This is described further below.

To measure the externally applied magnetic field B₀, the microwave frequency is swept, and the current change is monitored by lock-in detection 17 simultaneously. The change of the current is measured as a function of the microwave frequency and reaches its maximum at the resonant frequency, from where the external field could be easily found as B₀=f/γ. FIG. 1(d) shows a frequency-swept EDMR spectrum where the external field B₀ is fixed at ˜25.2 mT, and the spectrum peak occurs at f≈708.5 MHz matching the applied magnetic field. The gyromagnetic ratio in our device is γ=28.03 (±0.0024) GHz/T, which is experimentally obtained through a linear fit as shown in FIG. 1(e). The value is slightly different from the free-electron gyromagnetic ratio (28.025 GHZ/T) due to the weak spin-orbit coupling of the charge carrier spin states.

In addition, the magnetic field response of the device 1 is shown to be linear over more than two orders of magnitude in the frequency domain (40 MHz to 6.0 GHZ). The upper limit of the resonant frequency is purely limited by the microwave source 13, and much higher resonance frequency can be achieved with compatible microwave sources (not illustrated). The minimum field that can be detected is limited by the intrinsic hyperfine field inside OSCs, which can be offset by applying an extra static magnetic field via microwire design (also not illustrated). In addition, for ultrasmall field detection, the influence of the geomagnetic field (˜50 μT) on the spin charge carriers in OSCs should be considered, which can be potentially removed by magnetic shielding.

To demonstrate the sensing capacity of the device 1, the permanent magnet 15 is used to create a magnetic field. The permanent magnet 15 provides a straightforward way to generate a wide range of static magnetic field with a known spatial distribution. This is described further below.

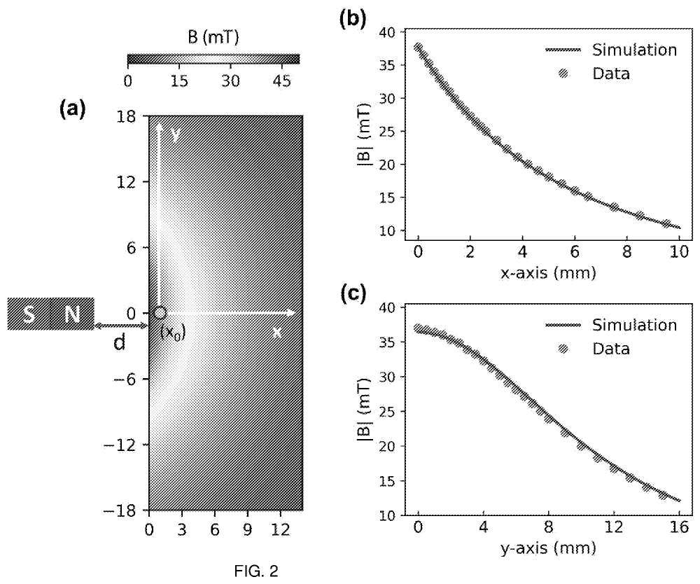

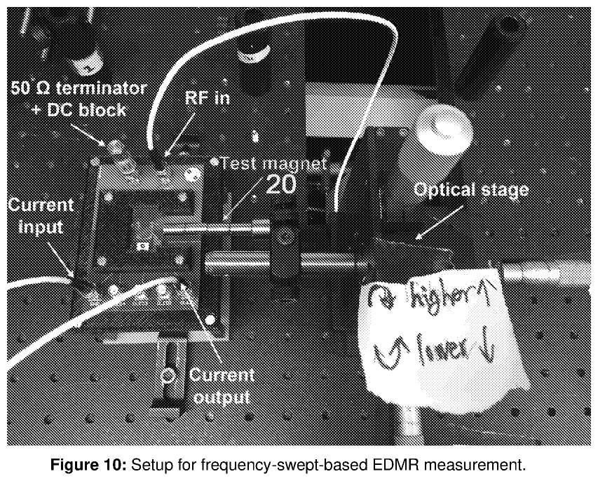

FIGS. 2(a)-(c) & 10 show EDMR-based magnetic field sensing of the preferred embodiment. FIG. 2(a) is a sketch of the setup of the preferred embodiment (not to scale). A cylindrical magnet 20 is located next to the device 1 with the cylindrical axis of the resulting magnetic field aligned in the plane of the device substrate 4. 2D simulation of the spatial distribution of the decaying magnetic field strength generated by the cylindrical magnet in a region of 14.0 mm×36.0 mm in the x-y plane with a distance of d˜10.0 mm from the magnet 20. The distance d corresponds to the half size of the device substrate 4 width as the OLED 2 is located at the centre of the rectangular glass substrate 4 (see FIG. 10) of the apparatus for frequency-swept-based EDMR measurements.

In use, a tiny gap (x₀) was initially set between the substrate 4 edge (not clearly seen in FIG. 10) and the magnet 20 at the starting position to avoid possible physical contact between them during the movement. The total distance between the OLED 2 (yellow dot) and the magnet is d+x₀. The x and y coordinates represent the horizontal and vertical movement directions in the laboratory frame, respectively. The OLED 2 functions as a point detector to measure the magnetic field strength generated by the magnet 20, and x₀ represents the starting position of the measurement. FIG. 2(b) is the detected magnetic field as the device 1 is stepped along the x-axis. The magnetic field strength is measured via the frequency-swept EDMR spectrum at each position, and the solid curve is the simulation with an estimated starting position of x₀˜0.20 mm. FIG. 2(c) shows the magnetic field detection as the device 1 is stepped along the y-axis with an estimated starting position of x₀˜0.40 mm.

FIG. 10 illustrates the experimental scheme, where the magnet 20 is located next to the device 1 and the OLED 2 operates as a point sensor of the magnetic field via a frequency-swept EDMR measurement. In OSCs the resonant peak frequency of the EDMR spectrum is only dependent on the strength of the external field B₀ rather than its direction, and this direction-independence characteristic is also observed in device 1 (described further elsewhere). Two independent measurements are made where the device 1 (as a point sensor) is stepped along x-direction (horizontally) and y-direction (vertically), separately. At each step of the movement, the microwave frequency is swept, and the magnitude of B is determined from the resonant frequency of the resulting EDMR spectrum. The measurement results show that the sensor can detect the magnetic field over a broad range with high accuracy, where the similarity between the experimental result and the computational simulation is about 99.8% (FIGS. 2b) and 98.6% (FIG. 2c), respectively.

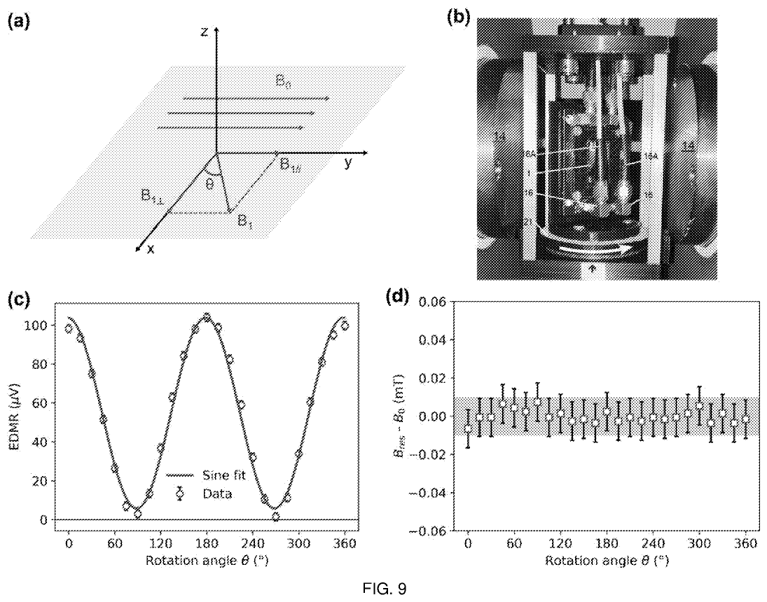

More particularly, to verify that the magnetic resonance condition is independent of the orientation of the external magnetic field B₀ in device 1, a separate angle dependent EDMR measurement is carried out. As demonstrated in FIGS. 9(a) & (b), the device 1 is mounted on a rotation stage 21 sitting between two electromagnet poles 14 (see FIG. 9). Instead of changing the orientation of the field B₀, the orientation of microwave field B₁ is changed equivalently. When the device 1 rotates, the orientation of the microwave field B₁ rotates in the horizontal x-y plane, labelled by angle θ as shown in FIG. 9(a). We find that: (1) the amplitude of the EDMR spectrum peak, which corresponds to the maximum change of the EDMR signal, is proportional to the projection of the B₁ field along the orthogonal direction to the B₀, and the relationship between the amplitude and the rotation angle can be well fit by a sine wave function; (2) the resonant frequency of the EDMR spectrum peak, which corresponds to the external magnetic field B₀ (f=B₀×γ), remains the same with 99.94% confidence.

FIG. 9(a) shows a rotation scheme where B₀ is the static magnetic field generated by the two electromagnet poles with fixed orientation, and B₁ is the oscillating field generated by the integrated microwave resonator 3 on the device 1. The orientation of field B₁ rotates in the horizontal x-y plane along with the stage rotating. FIG. 9(b) is a photograph of the experimental setup. Device 1 is mounted on PCB vertically, and the PCB is mounted on a rotation stage. FIG. 9(c) shows the amplitude of the resonant peak of the EDMR spectrum as a function of the rotation angle θ, where the frequency of the microwave field B₁ is fixed at 700 MHz and the magnetic field B₀ is swept. FIG. 9(d) shows the difference of resonant B₀ field between the experimental value extracted from the EDMR spectrum and the theoretical value calculated by B₀=fly, where f=700 MHz and γ=28.03 (GHz/T). The error bar corresponds to the magnetic field step accuracy (0.02 mT) in this measurement.

Observed was an exceedingly small EDMR signal at θ=90° and θ=270°, which is attributed to the spatial variation of the microwave field. The distance between the microwave element 6 and the OLED 2 is much smaller than the wavelength of the microwave radiation, hence the OLED 2 is in the near-field region of the B₁ field. As a result, the spatial orientation of the B₁ field is determined by the dimensions of the resonator 3 itself and the surrounding conductors, and the orientation varies slightly in the OLED 2 region. Therefore, there is always a small in-plane projection (B_{1//}) of the B₁ field during the whole rotation, and it plays a dominant role in the non-zero EMDR spectrums at θ=90° and θ=270°.

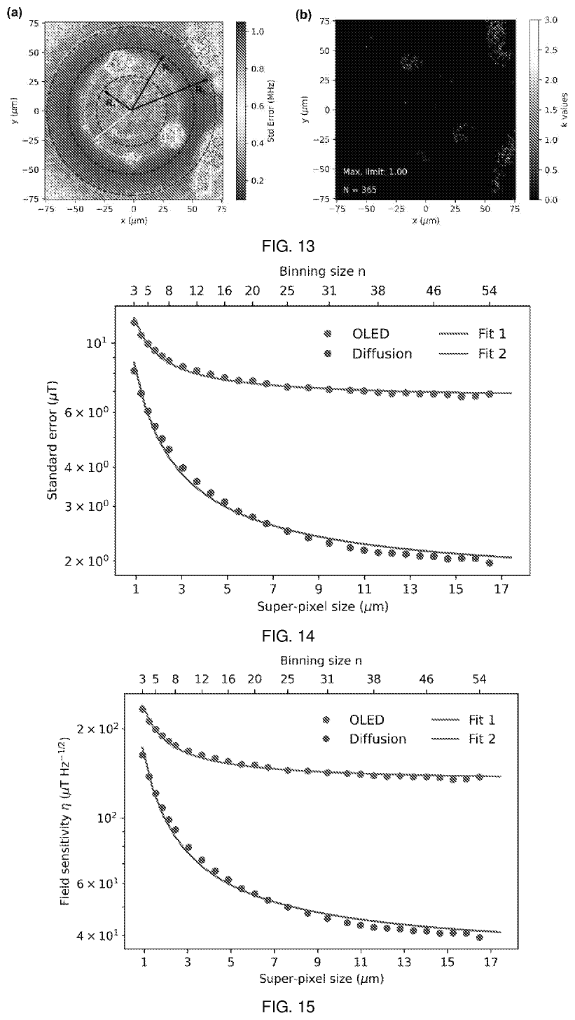

The small variation of resonant B₀ field value origins from the following aspects: (1) The influence of the SMA connectors 16A on the PCB. It was found that SMA connectors 16A of the SMA cables 16 in the preferred embodiment show weak paramagnetic behaviour under large external magnetic field, and it leads to a very weak disturbance on the Gauss probe 22 reading during the rotation. The disturbance becomes noticeable (at 0.1 mT scale) at some angles (60° to 120°) where the SMA connectors 16 are closest to the Gauss probe 22. It is noted that such disturbance has been removed in FIG. 13(d) through an independent and careful calibration process. (2) The finite step size of the sweeping magnetic field, which results in an uncertainty of the B₀ value extraction. (3) The uniformity of the static magnetic field B₀ between the two electromagnet poles. The uniformity of the field depends on the dimensions of the two poles, the gap between them, and the spatial location. In practice, the magnetic field detected by the Gauss probe 22 is always slightly different from the actual field the device 1 experiences, and such difference may even vary during the rotation if the rotation setup is not perfectly aligned with the magnet.

In respect of spatially resolved ODMR and magnetic field mapping, integrated device 1 is not only capable of sensing magnetic fields electronically via the EDMR method, but also provides optical accessibility for magnetic field mapping via a spatially resolved ODMR. To measure the spatially resolved ODMR, an optical microscope 23 (FIG. 3a) is used to image the OLED 2 onto a scientific complementary metal-oxide-semiconductor (sCMOS) camera 24, however, it will be appreciated any preferred optical imaging system can be used.

FIG. 3(a) is a sketch of the setup for spatially resolved ODMR. The inset shows the image of EL intensity captured by the sCMOS camera 24. The B field arrow represents the magnetic field gradient across the OLED 2 along x-axis direction in the horizontal x-y plane.

FIG. 3(b) shows the scheme used for pixel binning where n×n adjacent camera pixels are merged into one combined pixel called “super-pixel” via pixel binning process. The optical signal (EL intensity) of each super-pixel is the average of the signals of all the n×n individual camera pixels. FIG. 3(c) shows double Gaussian fits of ODMR spectrums of two super-pixels with binning size n=3. Super-pixel 1 and super-pixel 2 corresponds to the super-pixel at position of (−63.4 μm, 0.0 μm) and (52.4 μm, 0.0 μm) in (d), respectively. The solid circle dots label out the resonant peak position in the fit curves. FIG. 3(d) is a 2D spatial map of the resonance frequency (f_{ODMR}) of the ODMR spectrum of 166×166 super-pixels with binning size n=3. The entire region contains 500×500 pixels, and the super-pixel size is about 0.91(5) μm×0.91(5) μm (n=3). Weak EL signal is also observed outside the defined area of the OLED 2 due to the high hole conductivity of the PEDOT:PSS thin film. This provides the ODMR spectrums across the entire region. FIG. 3(e) in the most left figure (n=3) shows a zoom-in view of a local region (10×10 super-pixels) of the 2D map in FIG. 3(d). The other four figures show the magnetic field map of the same region with different binning sizes.

As noted, the measurement setup is sketched in FIG. 3a, where the device 1 is mounted on a 3-axis optical stage 25 and the light emitted from the OLED 2 is collected by an infinity-corrected objective and refocused onto the camera 24 through a tube lens. The optical signal (EL intensity) is finally detected and acquired by the camera 24 via optical microscope 23. A square-wave microwave signal (0.5 Hz) is applied, and the difference in EL between the on and off cycles is measured with the camera 24. The microwave frequency is swept, and a similar image taken at each frequency. Each pixel of the camera therefore measures an ODMR spectrum associated with a spatial region of the OLED 2. As a result, the 2D EL image is captured by the camera 24 with a small modulation frequency (0.5 Hz), and then ODMR spectrum of each pixel is achieved through image post processing and analysis, namely spatially resolved ODMR. See more details in the Methods. To improve the signal-to-noise ratio (SNR) of the ODMR spectrum so that the magnetic field can be more precisely measured, the camera 24 pixels are binned up to form super-pixels (see FIG. 3b). FIG. 3(c) shows the ODMR spectrums of two individual super-pixels at separate locations. Though the SNR of the data is still relatively low (˜4) after binning, the spectrum can be well fitted using a double Gaussian function, from where the magnetic field is acquired by converting the resonant frequency (f_{ODMR}) to field strength (|B|). FIG. 3(d) shows a 2D map of the measured magnetic field across the entire region (152.5 μm×152.5 μm) with super-pixel size of 0.91 μm (binning size n=3).

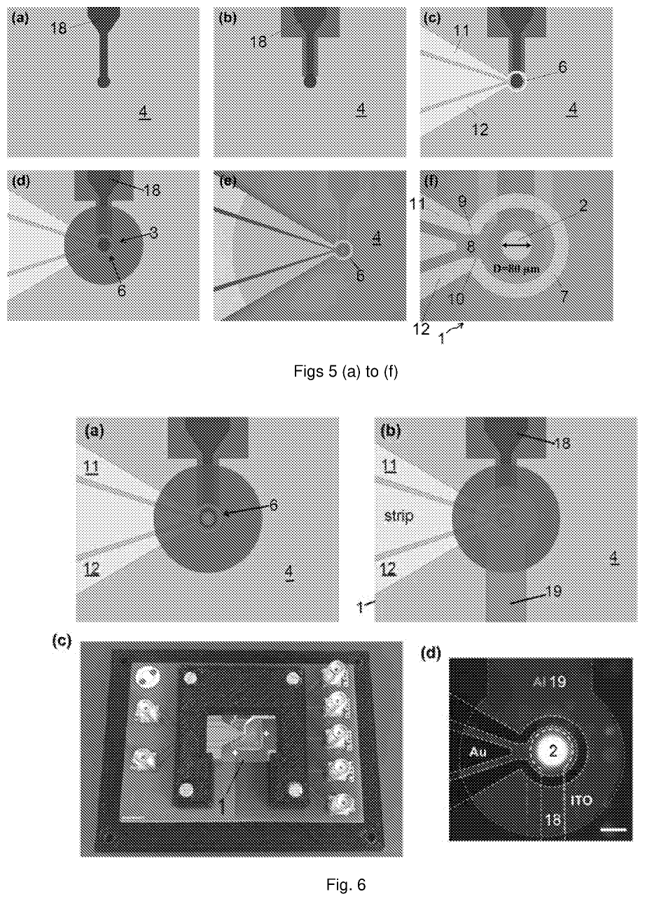

The super-pixel size is above the optical diffraction limit of the microscope objective (λ/(2NA)=714 nm) for a typical EL wavelength of Δ=600 nm. The measured field shows a clear and smooth gradient change along the x-axis direction while remains the same along the y-axis direction, which is consistent with the orientation of the test magnet. Further, there is a barely visible ring feature in the middle part of the field map, which has a blurry edge and is almost invisible. It turns out that such ring feature is associated with overall SNR of the ODMR spectrums at difference regions, which results in a spatial variation of the uncertainty of the fitting results (see FIG. 13). The EL signal and the related ODMR spectrum is observed across the whole field of view, which is much larger than the defined size (D=80 μm) of OLED 2 in the photolithography process (see FIG. 5(d)). The reason is due to the high hole conductivity in the PEDOT:PSS (>1,000 S cm 1), as a result, the injected holes from the ITO electrode 18 diffuse in the PEDOT:PSS layer along the in-plane direction, leading to a EL emission over a much larger area. FIG. 3(e) shows a zoom-in view of a local region (9.1 μm×9.1 μm) of the 2D map in FIG. 3(d) with a variety of binning size. As the binning size increases, the spatial resolution of the field mapping decreases; accordingly, the standard error of the fit decreases, indicating the enhancement of the measurement sensitivity.

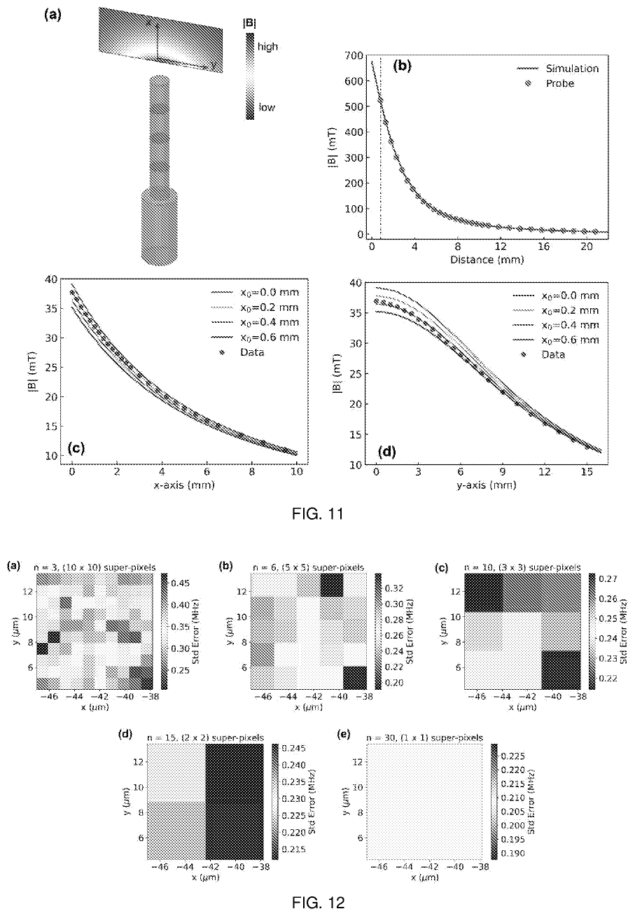

FIG. 11 shows the method of simulation of the preferred embodiment. In FIG. 11(a), a magnetic field simulation of the test magnets using ANSYS Electronics (Maxwell 3D Design with Magnetostatic Solution). The 2D map represents the spatial distribution of the strength of the static magnetic field generated by the magnet in a region of 14.0 mm×36.0 mm in the x-y plane with a gap distance of d=10.0 mm from the top surface of the magnet. Please note that the test magnets are not drawn to scale. Dimensions and material properties of these cylindrical magnets are summarized in Table 1. FIG. 11(b) shows the comparison of the simulated magnetic field and the experimentally measured field using Hall probe gaussmeter. The strength of the magnetic field here is a function of the movement distance along the z-direction from the top surface of the magnet. We note that the total thickness of the Gauss probe 22 is about 1.6 mm, therefore the starting position for the Hall probe measurement is about 0.8 mm (half of the probe thickness) as labelled out by the dash line, where we positioned the probe right adjacent to the magnet. The similarity between the Hall probed field and the simulation field is 98.5%. Comparison of experimentally measured field (grey dots) and the simulated magnetic field (colour curves) with various starting position x₀, as a function of the movement distance along x-direction in FIG. 11(c) and along y-direction in FIG. 11(d), respectively. We note that the x-y coordinates in (c) and (d) is a local frame within the 2D map plane, which is labelled out separately in (a). Similarity between the measured field and the simulation field is 99.8% (x₀=0.2 mm) in (c), and 98.6% (x₀=0.4 mm) in (d). The similarity calculation formula is listed as below.

| | Diameter | Length | Edge radius | |
|---|---|---|---|---|
| | (mm) | (mm) | (mm) | Materials |
| Cylinder 1 (×4) | 7.0 | 12.0 | 0.2 | N48 |
| Cylinder 2 | 12.7 | 25.4 | 0.2 | N45 |

Table 1: It is noted that the parameters of diameter, length and material property are obtained directly from the product datasheet, and the edge radius is estimated based on our own measurements. The edge radius here refers to the smooth curvature of the surface edge of the magnet cylinder. In addition, the influence of the edge radius on the simulation field distribution is investigated by comparing simulation with edge radius 0.2 mm and simulation with edge radius 0.0 mm. We find: (1) for the far-field region (d>8.0 mm), the difference of the field between two cases, both amplitude and direction, is negligibly small; (2) for the near-field region (d<5.0 mm around the edge area), the difference is still quite small but not negligible. Therefore, in the Main FIG. 2 where the distance d>10 mm, simulation field remains the same regardless the estimated value of the edge radius.
Definition of similarity:

$$s = 1 - \frac{1}{N} {\sum }_{i = 1}^{N} \frac{\vert p ( {x}_{i} ) - q ( {x}_{i} ) \vert}{[ p ( {x}_{i} ) + q ( {x}_{i} ) ] / 2} ,$$

where p(xᵢ) and q(xᵢ) are two independent data sets as a function of variable xᵢ.

In respect of FIG. 12, this shows the standard error calculation of spatially resolved ODMR in a local region of OLED 2 where standard error of the fit of the resonant peak frequency with a variety of binning size in the local region. FIG. 13(a) shows the spatial distribution of the standard error (SE) of the resonant peak frequency of the ODMR spectrums in the full field of view. The 2D map demonstrates three distinguishable regions: (1) the central region with R<R₂, where the SE is clearly larger than the surrounding regions. The reason of the large SE in this region is because of the electrical coupling between the resonator and the device electrodes. We suspect that the ‘wobbling’ feature noise from the resonator (see FIG. 7) is encoded into the device 1 where an electrical coupling between the ITO 18 and Al 19 electrodes is induced. Such electrical coupling is eventually transmitted to the device 1 output (both current and the EL), reducing the overall SNR. (2) the ring region with R₂<R<R₃, where the SE is the smallest. The EL emission in this ring region is due to the high hole mobility in the PEDOT:PSS layer. In specific, holes are injected from ITO electrode 18 into PEDOT:PSS layer through the defined area (R_{OLED}=40 μm), then diffuse in the PEDOT:PSS layer along the in-plane direction outwards. Under the bias voltage, these diffusing holes are gradually injected into the emitting layer along the diffusion path, eventually forming excitons through combing with the electrons which are injected from the top Al electrode 19. As this is the diffusion region, the noise caused by the electrical coupling between the two electrodes 18 & 19 is much weaker compared to the central region. Therefore, the SE in this ring region is smaller than the central region. (3) The edge region with R>R₃, where the SE is large compared to ring region though it is also the diffusion region. The reason is because the EL signal is much weaker in this edge region, therefore the over SNR is much smaller.

FIG. 13(a) is a 2D map of the standard error of the resonant peak frequency fit with binning size n=3 (the whole region contains of 166×166 super-pixels). The OLED region refers to the region with R<R₁ and the diffusion region refers to the region with R₂<R<R₃. The yellow dash circle with radius R_{OLED} indicates the edge of the OLED 2 area defined by the photolithography process. Their values are: R₁=30 μm, R₂=54 μm, R₃=72 μm, R_{OLED}=40 μm. FIG. 13(b) shows the spatial distribution of outliers which are defined as the points whose value is out of the field range of (754 MHZ, 771 MHZ). The actual values of the resonant peak frequency and the standard error of those outliers are interpolated by adjacent points, the distance of which is indicated by k value. The selection of the values of those radiuses is to avoid the outliers while covering as many points as possible in each region. Those outliers are caused by defects during photolithography process and device 1 degradation during the measurement.

FIG. 14 shows standard error (SE) of double Gaussian fits of the spatially resolved ODMR spectrums with different binning sizes. Investigating the relationship quantitatively between the magnetic field sensitivity and the spatial resolution of the field mapping. In general, the magnetic field sensitivity is defined as the minimum detectable field Bₘᵢₙ, which corresponds to the error of an individual measurement. By combining the signal from neighbouring pixels, the measurement error can be reduced by \sqrt{N}=n times, where N is the total number of camera pixels in each individual super-pixel with binning size n (N=n×n), although this also reduces the spatial resolution. To account for the measurement time, the sensitivity is represented as η=Bₘᵢₙ×\sqrt{T}=SE(n)×\sqrt{T}, where SE(n) is the standard error (SE) of a single ODMR measurement of an individual super-pixel with binning size n, and T is the total data acquisition time for each microwave frequency step. T=400 s is used in the actual experiment (see the method of FIG. 15), and the SE of the measurement can be extracted from the fit of the ODMR spectrum.

Therefore, for magnetic field mapping with spatial resolution of ˜0.91(5) μm (corresponding binning size n=3) in FIG. 3(d), the magnetic field sensitivity is calculated to be ˜233.04 μT Hz^{-1/2} in the OLED region and ˜163.16 μT Hz^{-1/2} in the diffusion region, respectively. When the super-pixel size is increased to ˜14.64 μm (binning size n=48), the sensitivity is improved to ˜ 136.88 μT Hz^{-1/2} in the OLED region and ˜40.75 μT Hz^{-1/2} in the diffusion region, respectively. Although the measured sensitivity follows the general 1/n rule as mentioned above, the actual improvement ratio of the sensitivity (e.g., 163.16÷40.75≈4 time in diffusion region) is much smaller than the trade-off ratio of the spatial resolution 48÷3=16 times). It is thought the reason for this ratio inconsistency is because the SNR improvement through binning process is partially suppressed by device-related noises including the fluctuation of EL intensity caused by the electrical coupling between the OLED 2 and the resonator 3 (see FIG. 8), and other technical contributions.

In respect of the 1/n rules, reference is made to FIG. 15 concerning the sensitivity calculation of the spatially resolved ODMR. Here, magnetic field sensitivity of the spatially resolved ODMR as a function of super-pixel size in both OLED and diffusion regions. See more details about the region definition in FIG. 13. The data set in FIG. 15 can be fit by using function γ=a/x+b. The fit parameters are (1) for the OLED region: a=98.81 (±2.12), b=132.33 (±0.76); (2) for the diffusion region: a=127.55 (±2.44), b=33.77 (±0.87). The unit for parameter a and b is μT·Hz^{-1/2}·μm and μT·Hz^{-1/2}, respectively.

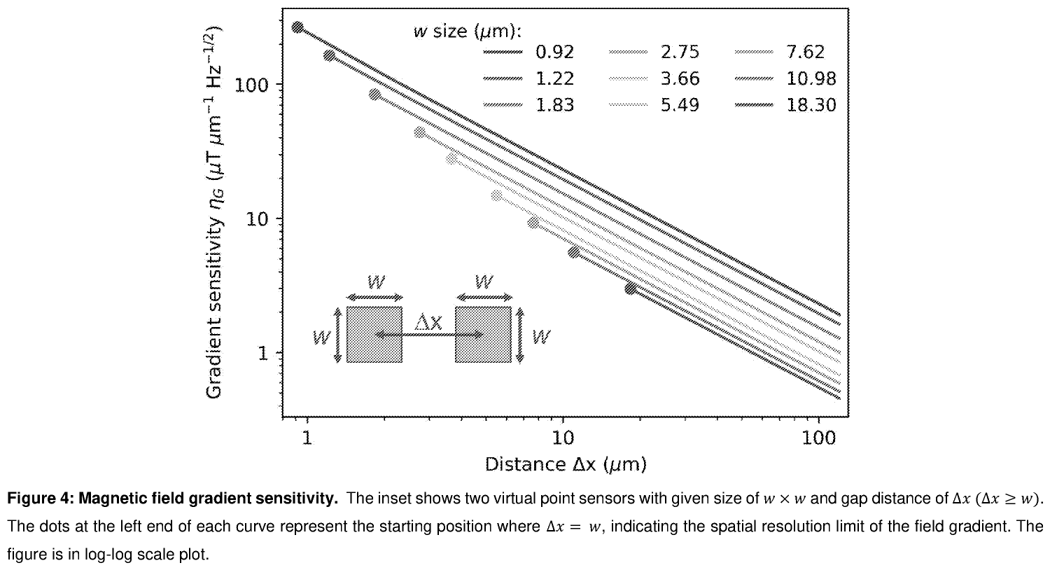

The magnetic field gradient sensitivity of device 1 is calculated from the uncertainty of the field gradient, which is given by G=ΔB/Δx, where ΔB=B(x₂)−B(x₁) is the measured magnetic field difference between two super-pixels located at x₁ and x₂, and Δx=x₂−x₁ is the distance between them (refers to the inset in FIG. 4). Based on the error propagation, the minimum detectable gradient δG is given as following:

$$\frac{{( δ G )}^{2}}{{G}^{2}} = \frac{{( δΔ B )}^{2}}{{( Δ B )}^{2}} + \frac{{( δ Δ x )}^{2}}{{( Δ x )}^{2}} \qquad ( 1 )$$

Because of ΔB=B(x₂)−B(x₁), So (δΔB)²=[δB(x₂)]+[δB(x₁)]², where δB(xᵢ) (i=1, 2) is the uncertainty of the magnetic field (or minimum detestable magnetic field). Here it is assumed that uncertainty of the field is location independent or ideally the same across the whole device, δB(x₂)=δB(x₁)=δB, resulting in:

$$δΔ B = \sqrt{2} \times δ B \qquad ( 2 )$$

Similarly, the following result:

$$δΔ x = \sqrt{2} \times δ x \qquad ( 3 )$$

where δx is the uncertainty of the distance measurement and we assume δx is location independent as well. For a digital distance measurement, the minimum uncertainty is equal to the super-pixel width (see the inset in FIG. 4 in the main content),

$$δ x = w \qquad ( 4 )$$

As the whole measurement system is fixed firmly on the optical table, and no relative movement between the camera 24 and device 1 has been previously observed, it is believed that the actual uncertainty of the distance measurement caused by vibration and relative displacement is negligibly small compared to w.

By substituting equations (2-4) into equation (1) and using G=ΔB/Δr, we can get:

$$\begin{matrix}\frac{{( δ G )}^{2}}{{G}^{2}} = \frac{2 {( δ B )}^{2}}{{( Δ B )}^{2}} + \frac{2 {( δ x )}^{2}}{{( Δ x )}^{2}} \\ = {G}^{2} [ \frac{2 {( δ B )}^{2}}{{( Δ B )}^{2}} + \frac{2 {( δ x )}^{2}}{{( Δ x )}^{2}} ] \\ = {G}^{2} \frac{2 {( δ B )}^{2}}{{( Δ B )}^{2}} + {G}^{2} \frac{2 {( δ x )}^{2}}{{( Δ x )}^{2}} \\ = \frac{{( Δ B )}^{2}}{{( Δ x )}^{2}} \frac{2 {( δ B )}^{2}}{{( Δ B )}^{2}} + {G}^{2} \frac{2 {( δ x )}^{2}}{{( Δ x )}^{2}} \\ = \frac{2 {( δ B )}^{2}}{{( Δ x )}^{2}} + \frac{2 {{G}^{2} ( δ x )}^{2}}{{( Δ x )}^{2}} \\ = \sqrt{2} {\frac{δ B}{Δ x} [ 1 + {( \frac{δ x}{δ B} )}^{2} {G}^{2} ]}^{1 / 2}\end{matrix} \qquad ( 5 )$$

Equation (5) can be rewritten as below:

$$( δ G ) = \sqrt{2} {\frac{δ B}{Δ x} [ 1 + {( \frac{δ x}{δ B} )}^{2} {( \frac{Δ B}{Δ x} )}^{2} ]}^{1 / 2} \qquad ( 6 - 1 )$$

$$( δ G ) = \sqrt{2} \frac{δ B ( w )}{Δ x} {\{ 1 + {[ \frac{w}{δ B ( w )} ]}^{2} {( \frac{Δ B}{Δ x} )}^{2} \}}^{1 / 2} \qquad ( 6 - 2 )$$

In the above equation (6-1), δB is the minimum detectible magnetic field (or uncertainty of the magnetic field as mentioned above), and it depends on the super-pixel size w (or binning size n) as shown in FIG. 14; δx=w is the uncertainty of the distance measurement as shown in Equation (4). Equation (6-1) can also be rewritten as equation (6-2) which shows all the independent variables: w, Δx, and ΔB.

According to equation (6-2), δG is a monotonic increasing function of variable ΔB with fixed value of w and Δx. Therefore, the minimum detectable gradient δG can be further decreased by choosing the minimum field difference (ΔB)ₘᵢₙ=\sqrt{2}×δB as shown in equation (2). By plugging (ΔB)ₘᵢₙ=\sqrt{2}×δB into equation (6-2), we can get δG as below:

$$( δ G ) = \sqrt{2} {\frac{δ B ( w )}{Δ x} [ 1 + 2 {( \frac{w}{Δ x} )}^{2} ]}^{1 / 2} ( Δ x \geq w ) \qquad ( 7 )$$

Finally, the magnetic field gradient sensitivity η_{G} is given as below:

$$\begin{matrix}{η}_{G} = ( δ G ) \sqrt{T} \\ = \sqrt{2 T} {\frac{δ B ( w )}{Δ x} [ 1 + 2 {( \frac{w}{Δ x} )}^{2} ]}^{1 / 2}\end{matrix} \qquad ( 8 )$$

In the equation (8), all uncertainties (or errors) should be relatively small to justify the error propagation analysis above.

Alongside magnetic mapping, the device 1 can also be used to measure magnetic field gradients at μm scales. The field gradient is defined as G=ΔB/Δx, where ΔB is the difference of the measured magnetic field between two super-pixels with size of w×w acting as two virtual point sensors, and Δx is the center-to-center distance between them. The averaged gradient along the x-axis in FIG. 3(d) is estimated as ˜3.7 μT/μm (ΔB≈555.7 μT, Δx≈151.0 μm), while no clear gradient is observed along the y-axis due to the device alignment relative to the orientation of the magnet (see FIG. 2a). Further, the minimum detectable field difference (ΔB)ₘᵢₙ is related to the magnetic field sensitivity (the minimum detectable magnetic field) which is dramatically impacted by the binning size; therefore, the field gradient sensitivity (or minimum detectable field gradient) is limited by the size of the virtual point sensors. In addition, the size of the virtual point sensors also sets a limit on the spatial resolution ((Δx)ₘᵢₙ=w) of the field gradient. Based on error propagation, magnetic field gradient sensitivity η_{G} can be calculated as a function of virtual pixel size w and the gap distance Δx.

For the details of the calculation refer to the FIG. 15. As shown in FIG. 4, the field gradient can be achieved at μm scale with a relatively low gradient sensitivity; and in general, the gradient sensitivity can be improved by either increasing the virtual pixel size or the gap distance or increasing both as a cost of the spatial resolution. All the noises that limit the magnetic field sensitivity as mentioned above are understood to limit the gradient sensitivity as well.

One significant challenge of using any resonance-based technique for magnetic field sensing is the measurement time to find the resonant frequency across a broad range, which can be time-consuming, particularly with small frequency step size and long averaging time for better SNR. We anticipate that operationally a coarse scan across a broad range followed by a fine scan across the resonance range can be used to shorten the measurement time. However, such an improvement may be limited by the resonance linewidth which sets the upper limit of the frequency step size. Another challenge is the field sensitivity in both EDMR and ODMR, especially the spatially resolved ODMR. This may be improved in a number of ways: firstly, by minimizing the sample-related noises, especially the electrical coupling between the resonator and the OLED through device architecture optimization. Secondly, the sensitivity can be further enhanced by employing coherent modulation techniques (e.g. Ramsey or dynamical decoupling schemes). One of the motivating factors for this study was the presence of reasonably long spin phase coherence times of polarons in organic devices at room temperature—T₂ approaching 1 μs at room temperature has been observed in EDMR measurements, and the use of perdeuterated organic materials may be used to increase these times. Concerted effort aimed at identifying or developing materials with even longer phase coherence times would seem to hold promise.

In contrast to NV-based detection where multiple resonant peaks may occur because of the different crystallographic axes of NV in diamond, there is only one resonant peak in our device sensor, sensitive to the strength of the external magnetic field regardless of the field orientation. This means that no alignment of the sensor is required in the detection of the field strength. This alignment-free characteristic can potentially be useful in applications where the magnitude rather than the direction of the field is of importance, and inaccuracy caused by improper orientation of the magnetometer can be reduced (i.e., Hall-effect probe). We note that the amplitude of the resonant signal is proportional to the projection of the microwave field B₁ along the static external field B₀, and that it reaches the minimum or even vanishes when B₀ is in parallel with B₁. The sensitivity issues this causes can be potentially solved by generating a B₁ field with large directional inhomogeneity across the OLED so that there is always a portion of B₁ field that is projected orthogonal to B₀, leading to measurable resonances regardless of the orientation of B₀.

In order to detect the direction of the magnetic field, we can potentially extend the device architecture with two mutually perpendicular metallic strip lines integrated underneath the OLED. This will provide an in-plane microwave field with arbitrary direction. Along with the out-of-plane microwave field from the already integrated resonator, there will be three independent microwave fields that are perpendicular to each other. By repeating the measurement with each microwave field, the corresponding vector components of the unknown magnetic field can be detected. We note that the use of the metallic strip lines may block the light emission and consequently limit the optical readout in ODMR. Additionally, these metallic layers including the top Al electrode of the device can distort the external magnetic field, posing more challenge for the precise vector measurement, especially at high magnetic fields.

Advantageously, device 1 provides an OLED-based integrated quantum magnetometer capable of both optical and electrical readout. Device 1 can work not only as a point sensor under electrical operation via bulk EDMR or ODMR, but also as a virtual array of sensors under optical readout via spatially resolved ODMR. The optical access allows for magnetic field mapping and a field sensitivity of 163.2 μT Hz^{-1/2} with a spatial resolution of 0.91 μm is achieved with device 1. This conceptually demonstrates electrically driven and OLED-assisted magnetic sensing and mapping with device 1 on a chip; the field sensitivity can be further improved by several approaches, including minimizing device-related noise by optimizing the device architecture; improve the SNR of spatially resolved ODMR by utilizing spin coherent manipulation; and reducing the resonance linewidth using deuteration materials. Device 1 provides a chip-scale and laser-free OLED-based platform for magnetic field sensing and mapping, with potential applications for ubiquitous quantum sensing and mapping which leverages the significant investment in consumer OLED technologies.

Turning now to the fabrication of the integrated microwave resonator 3, in order to have the optical access to the device 1, the resonator 3 structure and the OLED 2 should be laterally separated so that the light can emit out from the ITO/glass side of the substrate 4. The main challenge of integrating the resonator 3 with an OLED 2 on the same ITO-based glass substrate 4 was how to electrically isolate them from each other. Here we employ low-temperature atomic-layer-deposition (ALD) method for the insulating layer depositions, providing conformal and high quality electrically insulating layer with thin thickness. The main procedures are as follows:
1) prepatterned ITO (120 nm) on glass substrates (30.0 mm×20.0 mm×0.7 mm) was purchased from a commercial company.
2) prepare the first insulating layer Al₂O₃ between the ITO layer and the following resonator layer. The geometry of the insulating layer was patterned through the standard photolithography process (MA6 system with negative photoresist nLOF2020 and developer ZA826MIF), and the Al₂O₃ (45 nm) layer was deposited by low-temperature ALD, followed by the lift-off process in NMP bath.
3) prepare the resonator layer on top of the first insulating layer. The structure of the resonator was defined through the standard photolithography (the same as in step 2), and then metal layer of Ti (10 nm)/Au (500 nm)/Ti (10 nm) was thermally deposited in a thermal deposition chamber (Jurt J. Lesker) followed by standard lift-off process. The 10 nm Ti layers were adhesion layers.
4) prepare the second insulating layer on top of the resonator the same way as for the first insulating layer in step 2. This second insulating Al₂O₃ (45 nm) layer is to electrically isolate the resonator 3 itself from the top electrode of the OLED 2 which was deposited in the later device 1 fabrication process. The final layer structure of the resonator-integrated template is: bottom electrode layer of ITO (120 nm)/first insulating layer of Al₂O₃ (45 nm)/microwave resonator layer of Ti (10 nm)/Au (500 nm)/Ti (10 nm)/second insulating layer of Al₂O₃ (45 nm).

More particularly, reference is made to FIG. 5 where a micron-size OLED 2 with microwave resonator 3 were integrated on the same substrate 4. Such integrated device needs to possess good capability for both EDMR and ODMR measurements at room temperature, good electrical insulation between the OLED 2 from the resonator 3, and an open ITO surface for the implementation of the micron-size OLED 2 on top of it. To extract the light out of the device 1 from the bottom ITO electrode 18 side, the resonator 3 layer needs to be laterally separated from the ITO electrode 18. Gold (Au) is an excellent room-temperature conductor and resistant to most acids/chemicals and if preferred for the resonator 3 layer. The key procedure of integrating the resonator 3 with an OLED 2 on the same ITO-based glass substrate 4 is how to electrically isolate the resonator 3 layer from the two electrode layers 18 & 19 of the OLED 2, which are the bottom ITO electrode 18 as anode, and the top Al electrode 19 as cathode. Here we employ low-temperature atomic-layer-deposition (ALD) method for the insulating layer deposition. Unlike thermal evaporation and e-beam evaporation which have poor step-edge coverage, ALD method is conformal and provides very high-quality insulating layer even with small layer thickness, and this is essential to electrically isolate some areas with sharp edges.

Referring particularly to FIG. 5, FIG. 5(a) shows the patterned ITO electrode 18 on the glass substrate 4. The diameter of the electrode end-circle is ˜120 μm. FIG. 5(b) shows the first insulating layer on top of ITO electrode 18, and FIG. 5(c) shows the microwave omega-shape resonator 3. The end of ITO electrode 18 sits in the middle of the omega-shape centre, and the intersection between the resonator 3 and the ITO is electrically isolated by the first insulating layer. FIG. 5(d) shows the second insulating layer on top of the resonator 3. There is an opening hole in the middle of the insulating layer which defines the geometry of the active area for the OLED 2. FIG. 5(e) is a photograph of the resonator-integrated template. The right side of the resonator 3 shows more yellowish colour, indicating the area covered by the second insulating layer and FIG. 5(f) is a zoomed view of the template, which shows a clear OLED 2 area patterned in the centre of the resonator and the diameter of the patterned area is ˜80 μm. The inner diameter of the resonator is ˜200 μm. It is noted that the whole layer structure is as following: glass (0.7 mm)/ITO (120 nm)/Al₂O₃ (45 nm)/Ti (10 nm)/Au (500 nm)/Ti (10 nm)/Al₂O₃ (45 nm).

The prepatterned ITO/glass substrates 4 are purchased from Kintec Company (Hong Kong). The ITO substrates are cleaned by standard cleaning procedure and dried out in the vacuum drying oven at 120° C. overnight before usage. The glass substrate dimension is: 30.0 (±0.05) mm×20.0 (±0.05) mm×0.7 (±0.01) mm. We note that shadow mask, which will be used for thermal deposition of the top Al 19 electrode of OLED 2, is precisely cut by laser based on the substrate dimension. The precision of the shadow mask dimension is particularly important for the good alignment between the substrate and the shadow mask, which is the key step in the later OLED 2 fabrication process (see FIG. 6).

The photoresist structures for the two insulating layers and the microwave resonator 3 layer are prepared through the standard photolithography process using MA6 system, using negative photoresist nLOF2020 and developer ZA826MIF with optimized parameters. The details of the photolithography steps are as following:
1) Spin nLOF2020 on the substrate at 3000 RPM for 30 s, resulting in photoresist layer thickness of ˜2.3 μm
2) Prebake the photoresist at 115° C. for 1 min
3) UV exposure for 4.5 s
4) Post exposure bake (PEB) the photoresist at 115° C. for 1 min
5) Develop in AZ826MIF for 1 min
6) DI water rinse for 20 s, and nitrogen gun dry
7) Further bake at 115° C. for 2 mins to remove any water residue
8) Post plasma cleaning for 10 mins (plasma etching rate ˜30 nm/per min)

Al₂O₃ was selected as the insulating material because of its excellent electrical isolation property and, more importantly, its compatibility with the materials and fabrication methods that were used with the preferred embodiment. The breakdown field of Al₂O₃ by ALD at room temperature is about 8 MV/cm (or 0.8V/nm), so 45 nm thickness is thick enough for OLEDs, whose operational voltage is in range of 0 V-15 V. The ALD system is CNT Savannah S200. The precursors for Al₂O₃ in ALD are water vapor (H₂O) and Trimethylaluminum (TMA). The chamber temperature for the ALD process was set at 120° C. The chamber temperature cannot be set too high as it would solidate the photoresist and the following lift-off process will become exceedingly difficult. The temperature in principle can be lower such as 80° C., which will ease the following lift-off process, but the cycle time will increase, and the total deposition time will increase dramatically. There is a trade-off between the deposition temperature and deposition time cost. The total deposition time for 45 nm Al₂O₃ by ALD at 120° C. is about 9.5 hours.

Following the ALD, the lift-off procedure of Al₂O₃ was carried out by immersing the samples in the N-Methyl-2-pyrrolidone (NMP) bath. To allow the NMP to penetrate the conformal insulating layer and attack the photoresist below more rapidly, it was necessary to scratch the surface of sample manually and slightly at locations without pattern features. For the bottom insulating layer, the surface close to the edge of the substrate was relatively easily scratched as there are no patterns underneath; while for the top insulating layer, a cascade probe station and use the sharp metal probe-tip to crack the photoresist pillar inside the resonator gently top downwards was employed. After the scratch, samples were immerged in the NMP bath on hotplate at 100° C. in a fume cupboard, until the lift-off procedure is completed.

For the layer deposition of resonator 3, the substrates with pre-patterned photoresist structure were transferred to a thermal evaporation chamber (Jurt J. Lesker) for the metal deposition. The vacuum condition was of ˜10⁻⁶ mbar, and the layers stack is Ti (10 nm)/Au (500 nm)/Ti (10 nm). The first 10 nm Ti layer was deposited as adhesion layer for the following Au deposition onto the glass surface. For the Au layer deposition, the first 100 nm was deposited with a low rate of 0.5 A/s, to minimize the heating effects on the pre-patterned photoresist structure, such as deforming or softening; the next 400 nm was deposited with a high rate of 2 A/s for time saving. The second 10 nm Ti layer is deposited as another adhesion layer for the spin-coating photoresist in the following photolithography procedure. Standard lift-off was followed in the NMP bath at 100° C.

FIG. 6(a) shows a sketch of the device 1 fabrication where a micron-size OLED 2 is fabricated inside the active area (D˜80 μm) and FIG. 6(b) the top Al electrode 19 is deposited by using a well aligned shadow mask. FIG. 6(c) is a photograph of the PCB platform for the device 1 mounting and electrical connection. The device 1 is mounted onto the PCB via a 3D printed plastic lid. The device 1 is electrically connected to the PCB via pogo pins (both AC for the resonator 3 and DC for the OLED 2). The OLED 2 is encapsulated by using a square glass coverslip (10 mm×10 mm) with a cavity (300 μm depth) in it to avoid physical contact with the top Al electrode 19. FIG. 6(d) is a photograph of the device 1 under operation. Profiles of the bottom ITO electrode 18, the top Al electrode 19, and the Au resonator 3 are highlighted using dashed lines. There is a small offset of the top Al electrode 19 from the centre, which is due to the manual alignment of the shadow mask through the OLED 2 fabrication procedure. The scale bar in (d) is 100 μm.

In the method of integrating a micron-size OLED 2 onto the resonator template, the resonator-integrated template was firstly cleaned by using UV ozone cleaner (purchased from Ossila) for 10 minutes, followed by spin coating of PEDOT:PSS ((purchased from Heraeus, Al 4083) at 3000 rpm for 1 min, which was baked for 2 hours at 120° C. on hotplate, resulting in a film thickness of about 35 nm. The sample was then transferred to a glove box (O₂<0.5 ppm, H₂O<0.5 ppm) where the SY-PPV solution (3 mg/ml in toluene) was spin coated at 1200 rpm for 1 minute and then baked for 2 hours at 60° C. on hotplate, resulting in a film thickness of about 80 nm. The SY-PPV solution was filtered using a PTFE syringe filters with pore size of 0.45 μm before spin coating to remove the polymer aggregates. The extra part of the SY-PPV layer on the top of the Au resonator 3 and the electrode pads were carefully removed by using cotton rod. Then sample was transferred to a high vacuum chamber (<10-8 mbar) for the deposition of LiF (1 nm)/Al (100 nm) using a shadow mask. The shadow mask was carefully aligned with the substrate so that Al was deposited to the target area only (top of the second insulating layer region) to avoid any possible short-circuit connection between the resonator 3 and the top Al electrode 19. After fabrication, the device 1 was encapsulated with a thin glass lid with recessed cavity using UV-activated epoxy inside the glovebox. A thin desiccant sheet (as moisture and oxygen absorber) was stuck onto the inner surface of the recessed cavity to prevent the device degradation in the air.

Referring to the EDMR measurements in FIG. 1 and FIG. 2, the OLED 2 was operated under a constant current of 0.5 μA (Keysight, SMU B2901A) at room temperature. The device 1 was mounted onto a PCB via a 3D printed lid-base board, and the device 1 was electrically connected to the PCB through pogo pins integrated on PCB, and the PCB was connected to all the measurement instruments using SMA cables 16. A signal generator 13 (SRS SG396) was connected to the microwave resonator 3 via electrodes 11, 12, providing an input microwave signal which was pulse modulated with 10 μs pulse width and 10 KHz modulation. The other end of the resonator 3 was connected to a 50Ω terminator. During the EDMR measurement, the resulting periodic changes in the device current were first amplified through a low-noise current amplifier (SRS SR570) utilising a 6 dB bandpass filter at 10 kHz, and then were detected by the lock-in amplifier (SRS SR865A).

In respect of spatially resolution of the ODMR measurement, reference is made to FIG. 3(a) where the device 1 was mounted on a 3-axis optical stage 25 and then aligned with an optical imaging system 23/24. The light emitting out of the device 1 from the ITO side was collected by an Infinity Corrected objective (20× Mitutoyo Plan-Apochromat Objective, NA=0.42, working distance=20.0 mm, focus length=10.00 mm), and then refocused onto a scientific CMOS camera (Andor iStar sCMOS 18U-A3 with working temperature of 0.0° C.) through a compatible tube lens (focal length=200.0 mm), where the EL intensity signal was detected and acquired by the camera 24. Under 20× magnification, the pitch between two adjacent pixels on the OLED 2 plane is about 0.30(5) μm. The OLED 2 was operated under a constant current of 0.5 μA (Keysight, SMU B2901A) at room temperature, and the resonator was connected to the signal generator 13 (SRS SG396).

A test magnet 20 was located next to the device 1, providing a static external magnetic field for Zeeman energy splitting. The microwave field output was modulated by a 0.5 Hz square-wave sequence with 200 operation sequences, the EL intensity signal of the on and off cycle was recorded by the camera 24 (exposure time of 980 ms) at each microwave frequency. The microwave frequency was swept, and eventually a full set of EL intensity data was recorded as a function of the microwave frequency. By calculating the averaged change of the EL signal between on and off cycle as a function of microwave frequency, we were able to obtain the ODMR spectrum at each camera pixel, namely a spatially resolved 2D ODMR spectrum.

The foregoing describes only one embodiment of the present invention and modifications, obvious to those skilled in the art, can be made thereto without departing from the scope of the present invention.

The term “comprising” (and its grammatical variations) as used herein is used in the inclusive sense of “including” or “having” and not in the exclusive sense of “consisting only of”.

1. A magnetic field sensor comprising:
an electrically inert and optically clear substrate having upper and lower surfaces;
a microwave or RF generator element disposed on an upper side of the substrate, the generator element configured to be connected to an electrode for connection to a microwave or RF generator; and
a heterostructure organic light emitting diode (OLED) disposed adjacent the microwave or RF generator element, the OLED being configured to be connected to a first electrode and a second electrode.

2. A sensor according to claim 1 wherein the microwave or RF generator element is a split ring resonator having an open arc length wherein each end of the split ring is configured to be connected to the microwave or RF generator, and the OLED is disposed centrally within the split ring resonator.

3. A sensor according to claim 1 or 2 wherein the substrate is formed from a glass, or from a rigid or flexible plastic material.

4. A sensor according to any one of claims 1 to 3 wherein the OLED includes a first or second electrode is disposed on the upper side of the substrate and the second or first electrode is disposed above the first electrode with a dielectric layer disposed therebetween.

5. A sensor according to any one of claims 1 to 4 wherein the second electrode is connected to a digital acquisition apparatus.

6. A sensor according to any one of claims 2 to 5 wherein the open arc length of the split ring resonator microwave or RF generator element is a predetermined length and defined by a chord having respective chord ends each configured to be connected to the electrodes for connection to the microwave or RF generator.

7. A sensor according to claim 4 wherein the first or second OLED electrode ITO is connected to a digital acquisition apparatus and the second or first OLED electrode is connected to a signal multiplexing unit.

8. A sensor according to any one of claims 1 to 7 including a permanent magnet adapted to provide a static magnetic field.

9. A sensor according to any one of claims 1 to 8 wherein the OLED is configured to be optically read through the substrate.

10. A sensor according to claim 9 wherein the OLED is optically read by a camera.

11. A sensor according to claim 10 wherein the camera is a digital camera having a CMOS based camera sensing element.

12. A sensor according to claim 10 or 11 including a microscope objective disposed intermediate the camera and the OLED.

13. A sensor according to any one of claims 1 to 12 wherein the OLED is disposed within AC magnetic field B₁ of the microwave generator element field.

14. A sensor according to any one of claims 1 to 13 configured such that the OLED is imaged by an imaging device to provide a virtual array of OLEDs therefrom.

15. A magnetic field sensor comprising:
one or more spaced apart electrically inert and optically clear substrates having upper and lower surfaces;
a plurality of spaced apart microwave or RF generator elements disposed on one substrate or one or more microwave or RF generator elements disposed on an upper side of each substrate, the microwave or RF generator elements each configured to be connected to an electrode for connection to a microwave or RF generator; and
a heterostructure organic light emitting diode (OLED) disposed adjacent each microwave or RF generator element, each OLED being configured to be connected to a first electrode and a second electrode.

16. A magnetic field sensor comprising:
an electrically inert and optically clear substrate having upper and lower surfaces;
a microwave or RF generator element disposed on an upper side of the substrate, the microwave or RF generator element configured to be connected to an electrode for connection to a microwave or RF generator; and
a plurality of heterostructure organic light emitting diodes (OLEDs) disposed adjacent the microwave or RF generator element, each OLED being configured to be connected to a first electrode and a second electrode.
